(19) United States
(12) Patent Application Publication
(10) Pub. No.: US 2006/0199381 A1
(43) Pub. Date: Sep. 7, 2006

(54) ELECTRO-CHEMICAL DEPOSITION APPARATUS AND METHOD OF PREVENTING CAVITIES IN AN ECD COPPER FILM

(76) Inventors: Hsueh-Chung Chen, Taipei Hsien (TW); Teng-Chun Tsai, Hsin-Chu City (TW); Ming-Sheng Yang, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/306,193

(22) Filed: Dec. 19, 2005

Related U.S. Application Data
(62) Division of application No. 10/249,007, filed on Mar. 10, 2003.

(51) Int. Cl. H01L 21/4763

(52) U.S. Cl. 438/643

(57) ABSTRACT

An improved electro-chemical deposition copper (ECD-Cu) apparatus and a method of preventing cavities in an ECD-Cu thin film are provided. The electro-chemical deposition apparatus has a bath tank, an anode positioned in the bath tank, and a spin plate for positioning a semiconductor wafer that is used as a cathode. The method, by alternating a spin direction of the spin plate between a clockwise direction and a counterclockwise direction, every 1 to 10 seconds, prevents an electrolyte solution of the bath tank from forming a stable vortex, and suppresses a phenomenon of forming cavities in the ECD-Cu thin film when bubbles of the vortex adhere to the wafer surface.

### CROSS REFERENCE TO RELATED APPLICATIONS

This is a divisional application of U.S. patent application Ser. No. 10/249,007, filed Mar. 10, 2003 by Hsuch-Chung Chen et al.

### BACKGROUND OF THE INVENTION

1. Field of the Invention

The present invention relates to an electro-chemical deposition copper (ECD-Cu) apparatus, and more particularly, to an improved ECD-Cu apparatus for preventing cavities in an ECD-Cu thin film.

2. Description of the Prior Art

As integration of integrated circuits increases, an RC time delay of metal connections will expectedly affect operation performance of an integrated circuit device. This problem is improved by using metals with a lower resistance for metal wires, or by reducing a parasitic capacitance of a dielectric layer between the metal wires. Copper is a possible choice for reducing RC time delay effects. In recent years, progress in process technology, such as a development of various diffusion barriers and advances of copper chemical mechanical polishing, etc., have allowed for problems encountered in copper processes to be overcome. Having solved a problem of embedded processes, and with a low resistivity and a good thermal conductivity of copper, application of copper will be wide-spread in semiconductor processes at 0.25 μm, or smaller, dimensions.

Technologies used for depositing a copper thin film include physical vapor deposition, chemical vapor deposition, electroless plating, electro-chemical deposition, and so forth at present. With advantages of low cost and high throughput, ECD-Cu is widely used in the semiconductor industry. During the process of electro-chemical deposition, the uniformity of the thin film surface is affected by factors such as a component of an electrolyte solution, temperature, current density, and a cleanness of the deposited surface. For example, the ECD-Cu thin film deposited by an electrolyte solution containing cyanide ions is smoother than that deposited by an electrolyte solution containing sulfate ions. Furthermore, a thin film surface deposited under a high temperature and with a high current density is more likely to exhibit roughness. Additionally, both impurities of the electrolyte solution and impurities of the deposited surface cause the deposited thin film to be more easily removed. Therefore, controlling the above-mentioned conditions is necessary to improve surface uniformity when performing an electro-chemical deposition process.

Moreover, to maintain a constant ion concentration across a deposited surface, using a spin electrode as a cathode causes the ion in the electrolyte solution to flow more smoothly to the deposited surface. Please refer to FIG. 1 and FIG. 2. FIG. 1 and FIG. 2 are schematic diagrams of a conventional electro-chemical deposition apparatus. Firstly, as shown in FIG. 1, a bath tank 10 has two portions, one is an inner tank 12, and the other is an outer tank 14, for storing the electrolyte solution. The main component of the electrolyte solution is copper ions. Both a reference electrode 16 and an anode/counter electrode 18 use a porous copper design to make laminar flows. A cathode/work electrode 20 is a spin electrode that is connected to a wafer 22 provided for deposition. When an external voltage or current is applied to the electro-chemical deposition system, a circuit comprising the anode, the electrolyte solution, and the cathode conducts, and a reduction reaction occurs on the cathode to leave the copper deposited on the wafer.

FIG. 2 is a schematic diagram showing the spin direction of the cathode. As shown in FIG. 2, for improving the uniformity of the deposited thin film, the cathode normally spins to ensure that the wafer 22 contacts fresh electrolyte solution continually during the electro-chemical deposition process. In conventional techniques, the cathode employs a single spin direction when performing an electro-chemical process, such that a stable vortex is formed in the solution and many bubbles are mingled with the vortex, which are hard to remove. These bubbles cause cavities formed in the thin film surface and affect the quality of the thin film.

### SUMMARY OF THE INVENTION

It is therefore a primary objective of this invention to provide an electro-chemical deposition apparatus and a method thereof to improve the quality of a deposited thin film.

The present invention provides an electro-chemical deposition (ECD) apparatus used in a semiconductor process. The ECD apparatus comprises a bath tank, an anode positioned in the bath tank, and a spin plate for positioning a semiconductor wafer that is used as a cathode. The spin plate spins alternately in a clockwise direction and in a counterclockwise direction when performing an electro-chemical deposition process.

The method of this invention comprises alternating a spin direction of the spin plate between a clockwise direction and a counterclockwise direction. This improves the shortcomings of forming a stable vortex as a result of the single spin direction in the conventional techniques. It also solves the problem of forming cavities in the deposited thin film surface due to an adherence of bubbles of the vortex to the wafer surface, thereby improving the quality of the deposited thin film.

It is to be understood that both the foregoing general description and the following detailed description are exemplary, but are not restrictive, of the invention.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a conventional electro-chemical deposition apparatus.

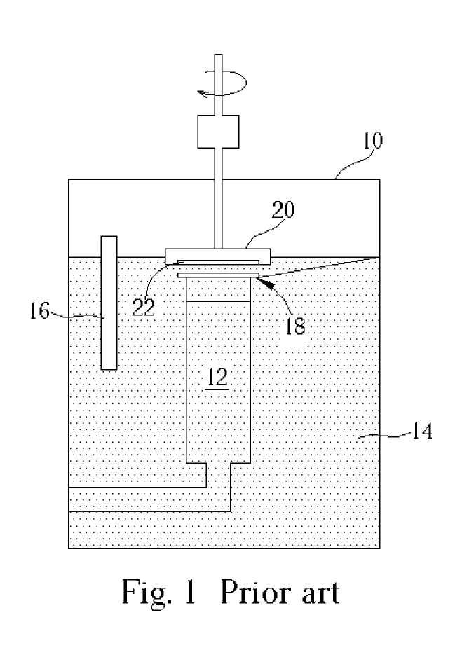

FIG. 2 is a schematic diagram showing a conventional spin direction of the cathode.

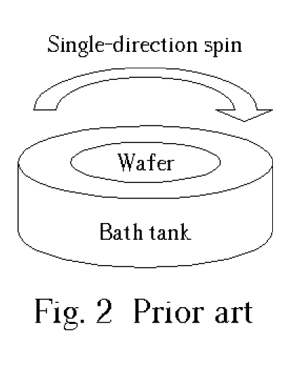

FIG. 3 is a schematic diagram of an electro-chemical deposition apparatus according to the present invention.

FIG. 4 is a schematic diagram showing a spin direction according to the present invention.

### DETAILED DESCRIPTION

The present invention provides an electro-chemical deposition (ECD) apparatus used in a semiconductor process. The ECD apparatus comprises a bath tank, an anode positioned in the bath tank, and a spin plate for positioning a semiconductor wafer that is used as a cathode. The spin plate alternately spins in clockwise and counterclockwise directions when performing an electro-chemical deposition process. The method of this invention comprises alternating a spin direction of the spin plate between a clockwise direction and a counterclockwise direction to prevent an electrolyte solution of the bath tank from forming a stable vortex, and to overcome the shortcomings of forming cavities in the ECD thin film caused by bubbles of the vortex adhering to the wafer surface, thereby improving a quality of the ECD thin film.

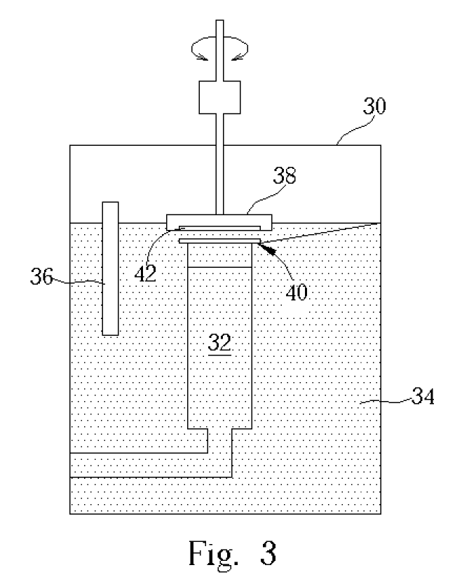

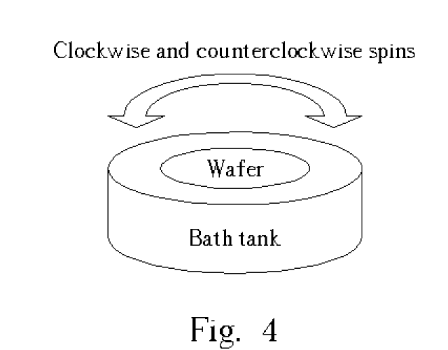

FIG. 3 and FIG. 4 are schematic diagrams according to the present invention. Please refer to FIG. 3, which is a schematic diagram showing an electro-chemical deposition apparatus according to the present invention. Similarly, a bath tank 30 has two portions, an inner tank 32, and an outer tank 34, for storing an electrolyte solution. A main component of the electrolyte solution is copper ions. Electrolyte solutions used in the semiconductor industry typically contain cyanide ions or sulfate ions. However, a copper sulfate (CuSo₄) solution is widely used in ECD processes in consideration of environmental protection. An additive is added to the electrolyte solution to ameliorate the uniformity of the deposited surface. In the preferred embodiment of the present invention, the electrolyte solution is a copper sulfate (CuSo₄) solution that has a flow rate of 1 to 15 liters per minute.

Both a reference electrode 36 and an anode/counter electrode 38 employ a porous copper design to make laminar flows. A cathode/work electrode 40 is a spin electrode that is connected to a wafer 42 provided for deposition. When an external voltage or current is applied to the electro-chemical deposition system, a circuit comprising the anode, the electrolyte solution, and the cathode conducts, and a reduction reaction occurs on the cathode to leave the copper deposited on the wafer. A direct current (DC) of −10 to 10 amperes (A), or an alternating current (AC) of −10 to 10 amperes (A) at a frequency of 5 to 20 hertz (Hz), is applied to the ECD apparatus of the present invention.

FIG. 4 is a schematic diagram showing the spin direction of the cathode according to the present invention. As shown in FIG. 4, for improving the uniformity of the deposited thin film, the cathode normally spins to ensure that the wafer 42 contacts fresh electrolyte solution continually during the electro-chemical deposition process. In the present invention, the cathode alternately spins in clockwise and counterclockwise directions every 1 to 10 seconds at 50 to 150 revolutions per minute (rpm). Alternating the spin direction in such a way prevents a stable vortex from forming in the solution, and prevents bubbles of the vortex from remaining on the deposited surface to form cavities on that surface.

In comparison with the prior art method, the present invention prevents a stable vortex from forming in the solution by means of alternating the spin direction of the spin electrode. Consequently, the phenomenon of bubbles adhering to the deposited thin film surface is eliminated and the cavities in the film surface are minimized to ameliorate the film surface uniformity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of preventing cavities in a thin film deposited by an Electro-Chemical Deposition Copper (ECD-Cu) apparatus, the ECD apparatus comprising a bath tank for storing an electrolyte solution, an anode positioned in the bath tank, and a spin plate for positioning a semiconductor wafer that is used as a cathode, the method comprising:
Alternating a spin direction of the spin plate between a clockwise direction and a counterclockwise direction every 1 to 10 seconds.

2. The ECD apparatus of claim 1 wherein the electrolyte solution is a copper sulfate (CuSo₄) solution.

3. The ECD apparatus of claim 1 wherein the electrolyte solution has a flow rate of 1 to 15 liters per minute.

4. The ECD apparatus of claim 1 being applied with a direct current (DC) of 1 to 10 amperes (A), or an alternating current (AC) of −10 to 10 amperes (A) at a frequency of 5 to 20 hertz (Hz).

5. The ECD apparatus of claim 1 wherein the spin plate is rotated at 50 to 150 revolutions per minute (rpm).
